(19) United States
(12) Patent Application Publication
(10) Pub. No.: US 2025/0160138 A1
(43) Pub. Date: May 15, 2025

(54) LIGHT EMITTING DISPLAY DEVICE

(71) Applicant: LG DISPLAY CO., LTD., Seoul (KR)

(72) Inventor: Hyeongjun LIM, Paju-si (KR)

(73) Assignee: LG DISPLAY CO., LTD., Seoul (KR)

(21) Appl. No.: 18/825,338

(22) Filed: Sep. 5, 2024

(30) Foreign Application Priority Data
Nov. 14, 2023 (KR) 10-2023-0157016

(51) Int. Cl. H10K 59/124; H10K 50/15

(52) U.S. Cl. CPC H10K 59/124; H10K 50/15

(57) ABSTRACT

A light emitting display device includes a substrate including a first pixel and a second pixel; a planarization layer on an entire surface of the substrate; a trench depressed into the planarization layer with a first depth, the trench including a first sidewall near the first pixel, a second sidewall near the second pixel and a bottom side connecting bottom ends of the first sidewall and the second sidewall; a first pixel electrode disposed at the first pixel on the planarization layer; a second pixel electrode disposed at the second pixel on the planarization layer; a hole functional layer disposed on the first pixel electrode and the second pixel electrode, and extended from a top side of the trench to a second depth smaller than the first depth on the first sidewall and the second sidewall of the trench; a filler from the bottom side to a third depth smaller than the second depth; a light emitting layer disposed on the hole functional layer, and extended from the top side of the trench to an upper surface of the filler on the first sidewall and the second sidewall; an electron functional layer disposed on the light emitting layer, and connected from the first pixel to the second pixel; and a common electrode disposed on the electron functional layer, and connected from the first pixel to the second pixel.

### CROSS-REFERENCE TO RELATED APPLICATION

This application claims the priority of Korean Patent Application No. 10-2023-0157016 filed on Nov. 14, 2023, which is hereby incorporated by reference in its entirety.

### BACKGROUND

### Field of the Disclosure

The present disclosure relates to a light emitting display device having a structure that prevents the lateral (or horizontal) leakage current occurring between neighboring pixels.

### Description of the Background

In particular, the light emitting display device which is a self-luminous display, has a structure in which a plurality of pixel areas including light emitting diodes are arranged. As the density of pixels increases over 4K ppi (i.e., 4,000 pixel per inch), the distance between pixels may be closer, and the distortion of pixel information may occur due to the lateral leakage current between pixels adjacent to each other in the lateral (or horizontal) direction. To ensure excellent display quality, it is necessary to develop a structure for a light emitting display device that is capable of suppressing a lateral leakage current between neighboring pixels.

### SUMMARY

Accordingly, the present disclosure, as for solving the problems described above, is to provide a light emitting display device that has a high pixel density and may prevent display quality deterioration due to lateral leakage current between neighboring pixels, as the distance between pixels narrows.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a light emitting display device includes a substrate including a first pixel and a second pixel; a planarization layer on an entire surface of the substrate; a trench depressed into the planarization layer with a first depth, the trench including a first sidewall near the first pixel, a second sidewall near the second pixel and a bottom side connecting bottom ends of the first sidewall and the second sidewall; a first pixel electrode disposed at the first pixel on the planarization layer; a second pixel electrode disposed at the second pixel on the planarization layer; a hole functional layer disposed on the first pixel electrode and the second pixel electrode, and extended from a top side of the trench to a second depth smaller than the first depth on the first sidewall and the second sidewall of the trench; a filler from the bottom side to a third depth smaller than the second depth; a light emitting layer disposed on the hole functional layer, and extended from the top side of the trench to an upper surface of the filler on the first sidewall and the second sidewall; an electron functional layer disposed on the light emitting layer, and connected from the first pixel to the second pixel; and a common electrode disposed on the electron functional layer, and connected from the first pixel to the second pixel.

In one aspect, the light emitting display device further comprises: a first dummy layer disposed between the bottom side of the trench and the filler, and including a same material with the hole functional layer. The hole functional layer is disconnected from the first dummy layer at a lower portion of the trench.

In one aspect, the filler contacts some of the hole functional layer at the first sidewall and the second sidewall.

In one aspect, the light emitting display device further comprises: a second dummy layer disposed on a central portion of the upper surface of the filler, and including a same material with the light emitting layer. The light emitting layer is extended from the top of the trench to the upper surface of the filler at the first sidewall and the second sidewall, and is physically disconnected from the second dummy layer.

In one aspect, the light emitting display device further comprises: a second dummy layer disposed on a central upper surface of the filler, and including a same material with the light emitting layer. The light emitting layer is physically connected to the second dummy layer at edge corners of the upper surface of the filler, and is electrically disconnected from the second dummy layer.

In one aspect, the hole functional layer is disconnected from the first pixel electrode to the second pixel electrode between the first sidewall and the second sidewall. The hole functional layer is physically disconnected from the electron functional layer by the filler

In one aspect, the light emitting display device further comprises: an air gap between the electron functional layer disposed on the first sidewall and the second sidewall and the filler; and an auxiliary filler filling the air gap.

In another aspect of the present disclosure, a light emitting display device includes a substrate including a first pixel and a second pixel; a planarization layer on an entire surface of the substrate; a trench depressed into the planarization layer with a first depth, the trench including a first sidewall near the first pixel, a second sidewall near the second pixel and a bottom side connecting bottom ends of the first sidewall and the second sidewall; a first pixel electrode disposed at the first pixel on the planarization layer; a second pixel electrode disposed at the second pixel on the planarization layer; a light emitting layer disposed on the first pixel electrode and the second pixel electrode, and extended from a top side of the trench to a second depth smaller than the first depth on the first sidewall and the second sidewall of the trench; a filler from the bottom side to a third depth smaller than the second depth; an electron functional layer disposed on the light emitting layer, and connected from the first pixel to the second pixel; and a common electrode disposed on the electron functional layer, and connected from the first pixel to the second pixel.

In one aspect, the light emitting display device further comprises: an air gap disposed between the electron functional layer disposed on the first sidewall and the second sidewall and the filler; and a hole functional layer under the light emitting layer.

In one aspect, the hole functional layer is disconnected from the first pixel electrode to the second pixel electrode between the first sidewall and the second sidewall. The hole functional layer is physically disconnected from the electron functional layer by the filler.

In a further aspect of the present disclosure, a light emitting display device includes a substrate including a first pixel and a second pixel; a planarization layer on an entire surface of the substrate; a trench depressed into the planarization layer with a first depth, the trench including a first sidewall near the first pixel, a second sidewall near the second pixel and a bottom side connecting bottom ends of the first sidewall and the second sidewall; a first pixel electrode disposed at the first pixel on the planarization layer; a second pixel electrode disposed at the second pixel on the planarization layer; a first light emitting layer disposed on the first pixel electrode and the second pixel electrode, and extended from a top side of the trench to a second depth smaller than the first depth on the first sidewall and the second sidewall of the trench; a filler from the bottom side to a third depth smaller than the second depth; a charge generation layer on the first light emitting layer, extending from the top side of the trench to an upper surface of the filler on the first sidewall and the second sidewall; a second light emitting layer disposed on the charge generation layer, and connected from the first pixel to the second pixel; an electron functional layer disposed on the second light emitting layer, and connected from the first pixel to the second pixel; and a common electrode disposed on the electron functional layer, and connected from the first pixel to the second pixel.

In one aspect, the light emitting display device further comprises: a first dummy layer disposed between the bottom side and the filler, and including a same material with the first light emitting layer. The first light emitting layer is disconnected from the first dummy layer at a lower portion of the trench.

In one aspect, the filler contacts some of the first light emitting layer at the first sidewall and the second sidewall.

In one aspect, the light emitting display device further comprises: a second dummy layer disposed on a central portion of the upper surface of the filler, and including a same material with the charge generation layer. The charge generation layer is extended from the top of the trench to the upper surface of the filler at the first sidewall and the second sidewall, and is physically disconnected from the second dummy layer.

In one aspect, the light emitting display device further comprises: a second dummy layer disposed on a central portion of the upper surface of the filler, and including a same material with the charge generation layer. The charge generation layer is physically connected to the second dummy layer at edge corners of the upper surface of the filler, and is electrically disconnected from the second dummy layer.

In one aspect, the light emitting display device further comprises: a hole functional layer disposed under the first light emitting layer.

In one aspect, the first light emitting layer and the hole functional layer are disconnected from the first pixel electrode to the second pixel electrode between the first sidewall and the second sidewall. The hole functional layer is physically disconnected from the electron functional layer by the filler.

In one aspect, the light emitting display device further comprises: an air gap surrounded by the second light emitting layer, the electron functional layer and the filler; and an auxiliary filler filling the air gap.

In one aspect, the light emitting display device further comprises: an auxiliary filler filled up to a depth smaller than the third depth, and contacting the charge generation layer inside the trench; and an air gap surrounded by the second light emitting layer, the electron functional layer and the filler.

In one aspect, the light emitting display device further comprises: an auxiliary filler filled up to a depth smaller than the third depth, and contacting the charge generation layer inside the trench; and an upper filler filled an upper space of the trench, the upper space corresponding to a space from the second light emitting layer on the auxiliary filler to the top side of the trench. The electron functional layer is disposed on the second light emitting layer and the upper filler.

The light emitting display device according to the present disclosure includes a trench structure surrounding each pixel in the plan view. In particular, the light emitting display device according to the present disclosure includes a vertical trench running to longitudinal direction and a horizontal trench running to latitudinal direction. Therefore, the charge generation layer of the organic emission layer stacked on the entire surface of the substrate may have a structure in which electrical connectivity is disconnected (or cut off) in the latitudinal direction (or X-axis direction) and the longitudinal direction (or Y-axis direction) in the plan view. As a result, image distortion due to the lateral leakage current between neighboring pixels may be prevented.

Particularly, the light emitting display device according to the present disclosure may have a deep-trench structure in which the depth of the trench is deep enough to disconnect the connectivity of the hole functional layer at the bottom of the trench, so the path for lateral leakage current may be cut off, in consideration of the process and method for manufacturing the light emitting display device. Further, to disconnect the electrical connectivity between the hole functional layer and the electric functional layer that may occur in the deep-trench structure, the light emitting display device according to the present disclosure may have a structure in which the bottom of the trench is filled with a non-conductive filler. As the result, it may be acquired to prevent lateral leakage current and to prevent the hole functional layer from being electrically connected to the electron functional layer.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure.

In the drawings:

FIG. 1 is a plane view illustrating a schematic structure of a light emitting display device according to an example of the present disclosure.

FIG. 2 is a circuit diagram illustrating a structure of one pixel according to an example of the present disclosure.

FIG. 3 is a plan view illustrating a structure of 2×2 pixels in the light emitting display device according to an aspect of the present disclosure;

FIG. 4 is a cross-sectional view along to cutting line I-I′ in FIG. 3, for illustrating the structure of a bottom emission type light emitting display device according to the aspect of the present disclosure;

FIG. 5 is an enlarged cross-sectional view, as for explanation of deep trench structure, illustrating a structure of part ‘A’ indicated by a dotted rectangle in FIG. 4;

FIG. 6 is a cross-sectional view, as for explanation of deep-trench structure having an insulating structure between the hole functional layer and the electron functional layer according to an aspect, illustrating a structure of part ‘A’ indicated by a dotted rectangle in FIG. 4;

FIG. 7 is a cross-sectional view, as for explanation of deep-trench structure having an insulating structure between the hole functional layer and the electron functional layer according to another aspect, illustrating a structure of part ‘A’ indicated by a dotted rectangle in FIG. 4;

FIG. 8 is an enlarged cross-sectional view, as for explanation of a light emitting display device having a deep-trench according a first aspect of the present disclosure, illustrating a structure of part ‘A’ indicated by a dotted rectangle in FIG. 4;

FIG. 9 is a cross-sectional view along cutting line II-II′ in FIG. 3, for illustrating a structure of a top emission type light emitting display device according to a second aspect of the present disclosure;

FIG. 10 is a cross-sectional view along cutting line I-I′ in FIG. 3, for illustrating a structure of a bottom emission type light emitting display device according to a third aspect of the present disclosure;

FIG. 11 is an enlarged cross-sectional view, as for explanation of a light emitting display device having a deep-trench according a third aspect of the present disclosure, illustrating a structure of part ‘B’ indicated by a dotted rectangle in FIG. 10;

FIG. 12 is an enlarged cross-sectional view, as for explanation of a light emitting display device having a deep-trench according a fourth aspect of the present disclosure, illustrating a structure of part ‘B’ indicated by a dotted rectangle in FIG. 10; and

FIG. 13 is an enlarged cross-sectional view, as for explanation of a light emitting display device having a deep-trench according a fifth aspect of the present disclosure, illustrating a structure of part ‘B’ indicated by a dotted rectangle in FIG. 10.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing aspects of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

Reference will now be made in detail to the exemplary aspects of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the case that “comprise,” “have,” and “include” described in the present specification are used, another part may also be present unless “only” is used. The terms in a singular form may include plural forms unless noted to the contrary.

In construing an element, the element is construed as including an error range although there is no explicit description.

In describing a positional relationship, for example, when the positional order is described as “on,” “above,” “below,” and “next,” the case of no contact there-between may be included, unless “just” or “direct” is used. If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing the elements of the present disclosure, terms such as the first, the second, A, B, (a) and (b) may be used. These terms are only to distinguish the elements from other elements, and the terms are not limited in nature, order, sequence or number of the elements. When an element is described as being “linked”, “coupled” or “connected” to another element that element may be directly connected to or connected to that other element, but indirectly unless otherwise specified. It is to be understood that other elements may be “interposed” between each element that may be connected to or coupled to.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in a co-dependent relationship.

Hereinafter, an example of a display apparatus according to the present disclosure will be described in detail with reference to the accompanying drawings. In designating reference numerals to elements of each drawing, the same components may have the same reference numerals as much as possible even though they are shown in different drawings. Scale of the elements shown in the accompanying drawings have a different scale from the actual for convenience of description, it is not limited to the scale shown in the drawings.

Hereinafter, referring to attached figures, we will explain about the present disclosure, in detail. FIG. 1 is a diagram illustrating a schematic structure of a light emitting display device according to the present disclosure. In FIG. 1, X-axis may be parallel to the extending direction of the scan line, Y-axis may be parallel to the extending direction of the data line, and Z-axis may represent the thickness direction of the display.

Referring to FIG. 1, the light emitting display device comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area DA and a non-display area NDA. The display area DA, which is an area for representing the video images, may be defined as the majority middle area of the substrate 110, but it is not limited thereto. In the display area DA, a plurality of scan lines (or gate lines), a plurality of data lines and a plurality of pixels P1, P2, P3 and P4 may be formed or disposed.

Here, the pixel P may represent any one of red, green and blue or any one of red, green, blue and white. A red pixel, a green pixel and a blue pixel may be grouped together, or a red pixel, a green pixel, a blue pixel and a white pixel may be gathered together to form one unit pixel. For an example, each pixel representing each color may be named a ‘sub-pixel’ and it may be explained that these ‘sub-pixels’ form one ‘pixel’. For another example, the pixels representing each color may be named ‘pixels P’ and it may be explained that three or four of these ‘pixels P’ are gathered together to form one ‘unit pixel’. Hereinafter, the latter case will be used for explaining the present disclosure.

The non-display area NDA, which is an area not representing the video images, may be defined at the circumference areas of the substrate 110 surrounding all or some of the display area DA. In the non-display area NDA, the gate driver 200 and the pad portion 300 may be formed or disposed.

The gate driver 200 may supply the scan (or gate) signals to the scan lines according to the gate control signal received from the timing controller 500. The gate driver 200 may be formed at the non-display area NDA at any one outside of the display area AA on the substrate 110, as a GIP (Gate driver In Panel) type. GIP type means that the gate driver 210 is directly formed on the substrate 110.

The pad portion 300 may supply the data signals to the data line according to the data control signal received from the timing controller 500. The source driving IC 410 may be mounted on the flexible circuit film 430. Further, the flexible circuit film 430 may be attached at the non-display area NDA at any one outside of the display area DA on the substrate 110, as a TAB (Tape Automated Bonding) type.

The source driving IC 410 may receive the digital video data and the source control signal from the timing controller 500. The source driving IC 410 may convert the digital video data into the analog data voltages according to the source control signal and then supply that to the data lines DL. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the signal cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

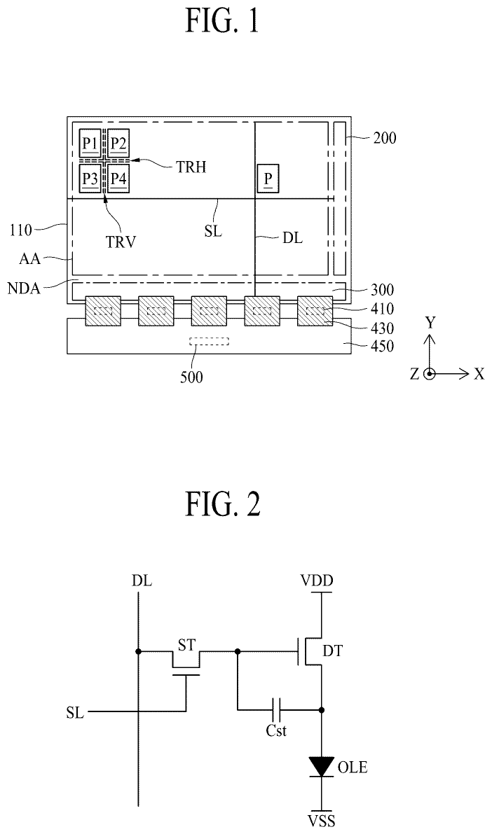

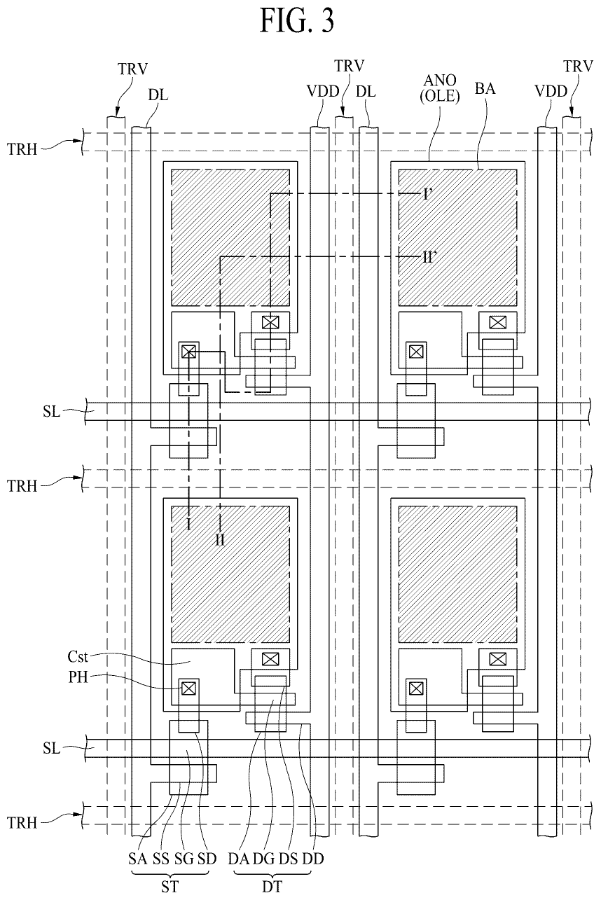

Hereinafter, referring to FIGS. 2 to 4, a light emitting display device according to an aspect of the present disclosure will be explained. FIG. 2 is a circuit diagram illustrating a structure of one pixel according to an aspect of the present disclosure. FIG. 3 is a plan view illustrating a structure of 2×2 pixels in the light emitting display device according to an aspect of the present disclosure.

At first, referring to FIGS. 2 to 3, one-pixel P of the light emitting display device may be defined by a scan line SL, a data line DL and a driving current line VDD. One pixel P of the light emitting display device may include a switching thin film transistor ST, a driving thin film transistor DT, a light emitting diode OLE and a storage capacitance Cst (or capacitor). The driving current line VDD may be supplied with a high-level voltage for driving the light emitting diode OLE.

For example, the switching thin film transistor ST may be disposed at the portion where the scan line SL and the data line DL is crossing. The switching thin film transistor ST may include a gate electrode SG, a semiconductor layer SA, a source electrode SS and a drain electrode SD. The gate electrode SG may be a portion of the scan line S. The semiconductor layer SA is disposed as crossing over the gate electrode SG. The portion of semiconductor layer SA overlapped with the gate electrode SG is defined as a channel region. The source electrode SS may be connected to or branched from the data line DL and the drain electrode SD may be connected to the driving thin film transistor DT. By supplying the data signal to the driving thin film transistor DT, the switching thin film transistor ST may play a role of selecting a pixel which would be driven.

The driving thin film transistor DT may play a role of driving the light diode OLE of the selected pixel by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended from the drain electrode SD of the switching thin film transistor ST. The drain electrode DD may be connected to or branched from the driving current line VDD, and the source electrode SD may be connected to a pixel electrode (or anode electrode) ANO of the light emitting diode (or light emitting element) OLE. A storage capacitance Cst may be disposed between the gate electrode DG of the driving thin film transistor DT and the pixel electrode ANO of the light emitting diode OLE.

The driving thin film transistor DT may be disposed between the driving current line VDD and the light emitting diode OLE. The driving thin film transistor DT may control the amount of electric current flowing to the light emitting diode OLE from the driving current line VDD according to the voltage level difference between the gate electrode DG source electrode DS.

The light emitting diode OLE may include a pixel electrode (or, anode electrode) ANO, an organic emission layer EL and a common electrode (or, cathode electrode) CAT. The light emitting diode OLE emits light according to electric currents controlled by the driving thin film transistor DT. The light emitting diode OLE may display an image by emitting light according to the electric currents controlled by the driving thin film transistor DT. The pixel electrode ANO of the light emitting diode OLE is connected to the source electrode DS of the driving thin film transistor DT, and the common electrode CAT is connected to the low-power line VSS to which a low potential voltage is supplied. The light emitting diode OLE is driven by the currents flowing from the driving current line VDD to the low-power line VSS by the driving thin film transistor DT.

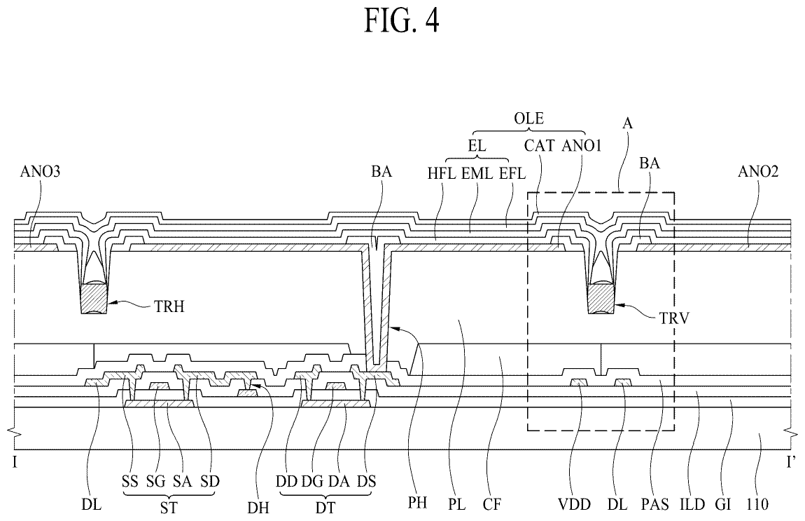

With further reference to FIG. 4, the cross-sectional structure of the light emitting display device according to the present disclosure will be described. FIG. 4 is a cross-sectional view along to cutting line I-I′ in FIG. 3, for illustrating the structure of a bottom emission type light emitting display device according to an aspect of the present disclosure.

A semiconductor layer SA of the switching thin film transistor ST and a semiconductor layer DA of the driving thin film transistor DT are formed on the substrate 110. Even though it is not shown in figures, a buffer layer may be further disposed between the semiconductor layers SA and DA and the substrate 110.

A gate insulating layer GI is deposited on the semiconductor layers SA and DA and the substrate 110. A gate electrode SG of the switching thin film transistor ST and a gate electrode DG of the driving thin film transistor DT are formed on the gate insulating layer GI. The gate electrode SG of the switching thin film transistor ST is disposed as overlapping with a portion of the semiconductor layer SA of the switching thin film transistor ST. In the switching thin film transistor ST, the area of the semiconductor layer SA that overlaps the gate electrode SG is defined as a channel area. Likewise, the gate electrode DG of the driving thin film transistor DT is disposed to overlap a portion of the semiconductor layer DA of the driving thin film transistor DT. The area of the semiconductor layer DA that overlaps the gate electrode DG in the driving thin film transistor DT is defined as a channel area.

An intermediate insulating layer ILD is deposited on the gate electrodes SG and DG and the gate insulating layer GI. A source and drain electrodes SS, SD, DS and DD are formed on the intermediate insulating layer ILD. In detail, the source electrode SS of the switching thin film transistor ST is formed that contacts one side of the semiconductor layer SA of the switching thin film transistor ST, and the drain electrode SD of the switching thin film transistor ST is formed that contacts the other side. The source electrode DS of the driving thin film transistor DT is formed that contacts one side of the semiconductor layer DA of the driving thin film transistor DT, and a drain electrode DD of the driving thin film transistor DT is formed that contacts the other side of the semiconductor layer DA.

The source electrode SS of the switching thin film transistor ST is branched from the data line DL. The drain electrode DD of the driving thin film transistor DT is branched from the driving current line VDD. In addition, the drain electrode SD of the switching thin film transistor ST is connected to the gate electrode DG of the driving thin film transistor DT through the drain contact hole DH formed in the intermediate insulating layer ILD.

The passivation layer PAS may be deposited on the top surface of the substrate 110 having the thin film transistors ST and DT. The passivation layer PAS is made of inorganic material such as silicon oxide (SiOx) and silicon nitride (SiNx). The color filter CF may be formed on the passivation layer PAS. The color filter CF may have a size little larger than the pixel electrode ANO which may be formed later and be disposed as fully overlapping with the pixel electrode ANO.

The planarization layer PL may be deposited on the passivation layer PAS and the color filter CF. The planarization layer PL may be the film layer for flattening the non-uniform surface of the substrate 110 on which the thin film transistors ST and DT are formed. To make the uneven surface condition of the substrate 110 to be flattened, the planarization layer PL may be formed of an organic material. The passivation layer PAS and the planarization layer PL may include the pixel contact hole PH exposing some portions of the source electrode DS of the driving thin film transistor DT.

The pixel electrode ANO may be formed on the planarization layer PL. The pixel electrode ANO may be connected to the driving drain electrode DD of the driving thin film transistor DT through a pixel contact hole PH formed at the planarization layer PL. The pixel electrode ANO may have various structures and different materials according to the emission type of the organic light emitting diode OLE. For an example, for the bottom emission type in which the light may be provided to the substrate 110 direction from the emission layer EL, the pixel electrode ANO may be made of a transparent conductive material. For example, the pixel electrode ANO of the bottom emission type may include oxide conductive material such as indium-zinc-oxide (IZO) indium-tin-oxide (ITO). For another example, for the top emission type in which the light may be provided to the upper direction opposite the substrate 110, the pixel electrode ANO may be made of metal materials having excellent light reflectance. FIG. 4 shows the structure of the bottom emission type.

A bank BA may be formed on the pixel electrode ANO. The bank BA may cover the circumference areas of the pixel electrode ANO and may expose most of middle areas of the pixel electrode ANO. The middle areas of the pixel electrode ANO exposed by the bank BA may be defined an emission area.

The trench TR may be disposed between the pixels formed by removing some portions of the bank BA and/or the planarization layer PL. The trench TR may include a horizontal trench TRH and a vertical trench TRV. The horizontal trench TRH may extend along the X-axis direction or transverse direction in a plane view on the substrate 110. The vertical trench TRV may extend along the Y-axis direction or longitudinal direction in a plane view on the substrate 110. One vertical trench TRV may be disposed at the left side and the right side of the pixel, and one horizontal trench TRH may be disposed at the upper side and the lower side of the pixel.

An organic emission layer EL may be deposited on the bank BA, the pixel electrode ANO and the trench TR. The organic emission layer EL may be deposited over the whole surface of the display area DA on the substrate 110, as covering the anode electrodes ANO and banks BA. In detail, the organic emission layer EL may be disposed as continuously connected over the first pixel P1, the second pixel P2 and the third pixel P3. However, some layers included in the organic emission layer EL may be disconnected at the trench TR. The disconnection structure of the organic emission layer EL may be explained as explaining the structure of the trench TR, in detail.

The common electrode CAT may be disposed on the organic emission layer EL. The common electrode CAT may be formed as a single layer connected on the entire surface of the substrate 110 including all of the first pixel P1, the second pixel P2 and the third pixel P3. Even though it is not shown in figure, a passivation layer may be further deposited on the common electrode CAT. The encapsulation layer may have a single layered structure or a multiple layered structure having organic layers and the inorganic layers alternately stacked.

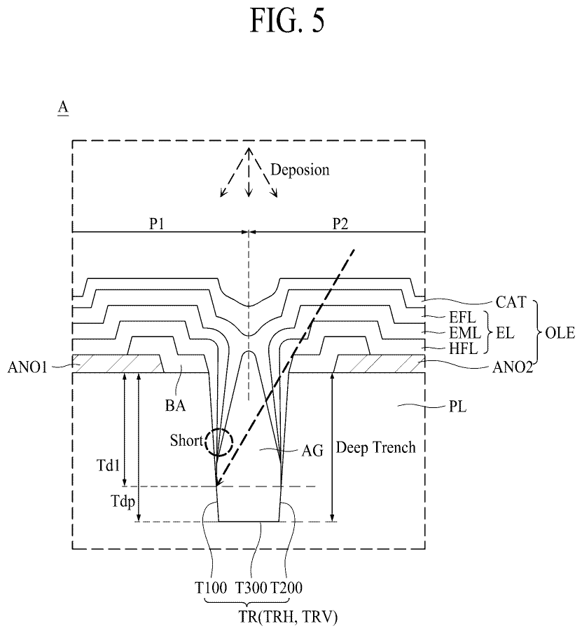

Hereinafter, referring to FIG. 5, the detailed structure of the trench (TRV, TRH) will be explained. FIG. 5 is an enlarged cross-sectional view, as for explanation of deep trench structure, illustrating a structure of part ‘A’ indicated by a dotted rectangle in FIG. 4. FIG. 5 is an enlarged cross-sectional view illustrating a structure of the vertical trench TRV, and the horizontal trench TRH may have the same structure. Hereinafter, the vertical trench TRV and the horizontal trench TRH will be explained as referring to terms of ‘trench TR’.

At first, the structure of the trench TR may be explained. On the planarization layer PL, a first pixel electrode ANO1 may be formed at the first pixel P1 and a second pixel electrode ANO2 may be formed at the second pixel P2.

A pixel defining layer or a bank BA may be formed at the circumferential areas of the first anode electrode ANO1 and the second pixel electrode ANO2 for defining emission areas. The bank BA may cover the circumferential areas and expose the central areas of the pixel electrodes ANO1 and ANO2.

Between a bank BA covering the first electrode ANO1 and a bank BA covering the second electrode ANO2, the trench TR may be formed. The trench TR may be formed between two neighboring banks BA.

In the present disclosure, a case where the bank BA may have a thickness of about 1 to 3 times the thickness of the pixel electrodes ANO1 and ANO2 will be described. In some cases, the thickness of the bank BA may be 10 times thicker than the thickness of the pixel electrodes ANO1 and ANO2. In these cases, the trench may be formed at the bank BA. However, in the present disclosure, as the thickness of the bank BA is not so thick, the trench TR is formed by depressing the planarization layer PL with a certain depth.

The trench TR may be formed by removing the planarization layer PL with a predetermined depth, for example, a trench depth Tdp. That is the trench is depressed in the planarization layer PL with the trench depth Tdp. As a result, the trench TR may have a first sidewall T100, a second sidewall T200 and a bottom side T300. The top side of the trench TR is open, and may be virtually set at the same height as the top surface of the planarization layer PL. The trench depth Tdp may be the vertical distance from the top side corresponding to the top surface of the planarization layer PL to the bottom side T300.

The first sidewall T100 may be set at one side where the first pixel electrode ANO1 is located, and the second sidewall T200 may be set at the other side where the second pixel electrode ANO2 is located. The bottom side T300 may be a horizontal plane connecting the lower ends of the first sidewall T100 and the second sidewall T200. As a top side of the trench TR is opened, it is not shown in figures. The top side of the trench TR may be a surface corresponding to an upper surface of the planarization layer PL or an upper surface of the bank BA.

After forming the trench TR, an organic emission layer EL is deposited thereon. The organic emission layer EL may have a structure in which a hole injection layer, a hole transport layer, a light emission layer, an electron transport layer and an electron injection layer are sequentially stacked on the pixel electrode ANO. The hole injection layer and the hole transport layer may be referred to a hole functional layer HFL, and the electron injection layer and the electron transport layer may be referred to an electron functional layer EFL.

The hole functional layer HFL and the electron functional layer EFL may be maintained an insulated state with the light emission layer EML between them. However, as a voltage difference is applied between the pixel electrode ANO and the common electrode CAT, the hole functional layer HFL may be received holes from the pixel electrode ANO and send them to the light emission layer EML, and the electron functional layer EHL may be received electrons from the common electrode CAT and send them to the light emission layer EML. Holes and electrons recombined in the light emission layer EML to form excitons. The exciton may be in an ‘excited state’ so it has high energy, but in the process of losing energy and going back to a ‘ground state’, the lost energy is emitted in the form of light.

In FIG. 5, the dotted arrow line may indicate the depositing diffusion angle of the evaporated gas of the hole functional layer HFL when depositing the hole functional layer HFL. When organic materials are deposited from an organic material deposition source placed at a certain distance from the substrate 110 where the trench TR is formed, the deposited organic material may be deposited on the substrate within a specified spraying angle. In the figure, the substrate 110 is shown below and the deposition source is placed at the top, but the deposition source may be placed below and the substrate 110 may be placed at the top, in an actual process.

When depositing an organic material on the substrate 110, the organic material may be deposited on the first sidewall T100 and the second sidewall T200 of the trench TR with a thickness gradually becoming thinner from the top side to the bottom side T300 of the trench TR depending on the depositing diffusion angle. The depth to the last position where the hole functional layer HFL is deposited on the first sidewall T100 and the second sidewall T200 may be referred to the deposition depth Td1. Here, a trench TR formed with a trench depth Tdp much deeper than the deposition depth Td1 may be referred to the “deep trench”. To implement a deep trench, the trench depth Tdp may be at least 102% to 150% of the deposition depth Td1. It may be formed deeper, but when it is deeper than above depth range, the trench TR may be too deep and collapse, or the productivity for manufacturing a trench may have a problem.

After forming the trench TR having the deep trench structure, the hole functional layer HFL may be deposited. The hole functional layer HFL may be deposited at a gradually decreasing thickness on the first sidewall T100 and the second sidewall T200 down to the deposition depth Td1. In a case, residues of the hole functional layer HFL may be deposited on the central portion of the bottom side T300. However, the hole functional layer HFL may not deposited at the left corner portion where the bottom side T300 and the first sidewall T100 meet, the right corner portion where the bottom side T300 and the second sidewall T200 meet, and the portion from the deposition depth Td1 to the bottom side T300 on the first sidewall T100 and the second sidewall T200. That is, the connectivity of the hole functional layer HFL may be disconnected at the bottom portion of the trench TR. Accordingly, holes, the charge element of the hole functional layer HFL, may not move between the first pixel P1 and the second pixel P2, thereby the hole function layer HFL may maintain an electrically insulated state per each pixel.

A light emitting layer EML may be deposited on the hole functional layer HFL. The light emitting layer EML may be deposited as following the same profile as the hole functional layer HFL. For example, the light emitting layer EML may be deposited with a gradually decreasing thickness on the first sidewall T100 and the second sidewall T200 down to the deposition depth Td1. In addition, the light emitting layer EML may not deposited at the left corner portion where the bottom side T300 and the first sidewall T100 meet, the right corner portion where the bottom side T300 and the second sidewall T200 meet, and the portion from the deposition depth Td1 to the bottom side T300 on the first sidewall T100 and the second sidewall T200.

An electron functional layer EFL may be deposited on the light emitting layer EML. The electron functional layer EFL may be deposited in a state where the top side of the trench TR, which is the entrance of the trench TR, is very narrowed due to the sequential stacking of the hole functional layer HFL and the light emitting layer EML. Therefore, the electron functional layer EFL is stacked on the upper part of the first sidewall T100 where the first pixel P1 is placed and on the upper part of the second sidewall T200 where the second pixel P2 is placed, so the electron functional layer EFL may have a structure connected over a central upper portion of the trench TR. Accordingly, the electron functional layer EFL may be formed as a single layer that connects all pixels over the entire substrate 110 including the first pixel P1 and the second pixel P2.

Here, inside of the trench TR, the electron functional layer EFL may be deposited on the first sidewall T100 and the second sidewall T200 with a similar profile as the light emitting layer EML. In detail, the electron functional layer EFL may also be deposited with the thickness that gradually decreases down to the deposition depth Td1, on the first sidewall T100 and the second sidewall T200. In addition, the electron functional layer EFL may not deposited at the left corner portion where the bottom side T300 and the first sidewall T100 meet, at the right corner portion where the bottom side T300 and the second sidewall T200 meet, and at the portion from the deposition depth Td1 to the bottom side T300 on the first sidewall T100 and the second sidewall T200.

In this structure, the electron functional layer EFL may be deposited on the light emitting layer EML having a very thin thickness near the portions corresponding to the deposition depth Td1. At the portions where the thickness of the light emitting layer EML is very thin, the electron functional layer EFL may be directly and electrically connected to the hole functional layer HFL. Here, the meaning of ‘the electron functional layer EFL is directly and electrically connected to the hole functional layer HFL’ may be as follows: The hole functional layer HFL and the electron functional layer EFL should be insulated each other with the light emitting layer EML there-between. However, when the thickness of the light emitting layer EML is too thin, the holes in the hole functional layer HFL and the electrons in the electron functional layer EFL may combine directly with each other. As the result, excitons may not be formed in the light emitting layer EML and electric current may flow from the hole functional layer HFL to the electron functional layer EFL.

Further, when operating the light emitting diode OLE, due to phenomena such as tunneling effect in the areas where the thickness of the light emitting layer EML is thinly deposited, the holes in the hole functional layer HFL and electrons in the electron functional layer EFL may be directly connected even with a very low voltage before the nominal voltage to drive the light emitting diode OLE is applied. As a result, the light emitting diode OLE may not work as a light emitting element.

As described above, in the deep trench structure to prevent lateral leakage current occurring between neighboring pixels through the hole functional layer HFL, the hole functional layer HFL and the electron functional layer EFL may be directly and electrically connected. This may cause a problem in which the light emitting diode OLE becomes inoperable.

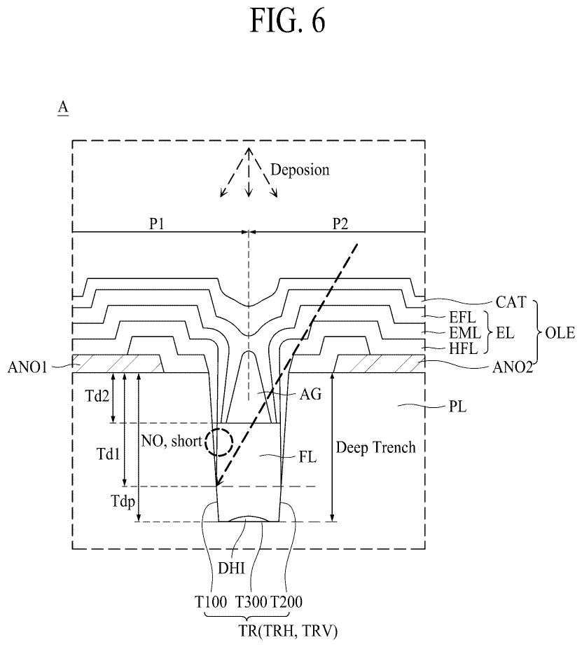

The present disclosure proposes a deep trench structure in which the insulation property between hole functional layer HFL and electron functional layer EFL is enhance. Referring to FIG. 6, one example of the deep trench structure according to the present disclosure will be explained. FIG. 6 is a cross-sectional view, as for explanation of deep-trench structure having an insulating structure between the hole functional layer and the electron functional layer according to an aspect, illustrating a structure of part ‘A’ indicated by a dotted rectangle in FIG. 4.

After forming a trench TR having the deep trench structure as explained above, a hole functional layer HFL may be deposited. The hole functional layer HFL may be deposited with a gradually decreased thickness on the first sidewall T100 and the second sidewall T200 down to the deposition depth Td1. Further, the hole functional layer HFL may not deposited at the left corner portion where the bottom side T300 and the first sidewall T100 meet, the right corner portion where the bottom side T300 and the second sidewall T200 meet, and the portion from the deposition depth Td1 to the bottom side T300 on the first sidewall T100 and the second sidewall T200. That is, the hole function layer HFL may be disconnected at the lower portion of the trench TR. Therefore, as holes, the charge element of the hole functional layer HFL, may not move between the first pixel P1 and the second pixel P2, so the hole functional layer HFL of each pixel P may be maintained in an isolated condition.

After that, the inside of the trench TR may be filled with a filler FL made of non-conductive material. The filler FL may be filled from the bottom side T300 of the trench TR to a certain height. The filler FL is an element for preventing the electrical conduction between the hole functional layer HFL and the electron functional layer EFL stacked under and over the light emitting layer EML, respectively, due to the thinly deposited light emitting layer EML.

The filler FL may fill the space from the bottom side T300 of the trench TR to a point at a certain depth, the point being apart from the upper surface of the planarization layer PL corresponding to the top side of the trench TR. This certain depth from the top side of the planarization layer PL to the top surface of the filler FL may be referred to a ‘filler depth Td2’. The the filler depth Td2 may be smaller than the deposition depth Td1. In addition, the filler depth Td2 may be set so that the non-conductive filler FL covers the lower portions of the hole functional layer HFL and does not form a portion where the light emitting layer EML is deposited too thinly. For example, the filler depth Td2 may be less than 75% of the deposition depth Td1.

When the filler depth Td2 is greater than 76% of the deposition depth Td1, the filler FL may not cover the area where the light emitting layer EML is thinly deposited, so the electron functional layer EFL deposited after the light emitting layer EML may be directly and electrically connected to the hole functional layer HFL. When the filler depth Td2 is less than 50% of the deposition depth Td1, no significant problems may occur. For example, when the organic emission layer EL includes only one light emitting layer EML, the filler FL may fill the entire trench TR. That is, the filler depth Td2 may be 0% of the deposition depth Td1, which has a ‘0 (zero)’ depth. When the filler FL fills the entire trench TR, each of the light emitting layer EML and the electron functional layer EFL that are stacked thereafter may connect the first pixel P1 and the second pixel P2 while passing over the top side of the trench TR. Even with this condition, since the hole functional layer HFL is disconnected between the first pixel P1 and the second pixel P2, the lateral leakage current may not occur. In addition, the filler FL may block the possibility of electrical connection between the hole function layer HFL and the electron functional layer EFL.

After the filler FL is filled to about 50% to 75% of the deposition depth Td1, the light emitting layer EML may be deposited. Then, as shown in FIG. 6, the connectivity of the light emitting layer EML may disconnected between the first pixel P1 and the second pixel P2. When the filler FL is filled to a position of 50% or less of the deposition depth Td1, the light emitting layer EML may be deposited as being connected between the first pixel P1 and the second pixel P2.

After that, the electron functional layer EFL may be deposited. The electron functional layer EFL may be deposited as being connected between the first pixel P1 and the second pixel P2 at the narrowed top side of the trench TR by sequentially stacking of the hole functional layer HFL and the light emitting layer EML. In addition, an air gap AG may be formed below the portion where the electron functional layer EFL is continuously deposited between the first pixel P1 and the second pixel P2. The air gap AG may refer to an empty space formed between the electron functional layer EFL and the filler FL. Although not shown in FIG. 6, a residual of the light emitting layer EML and a residual of the electron functional layer EFL may be sequentially stacked.

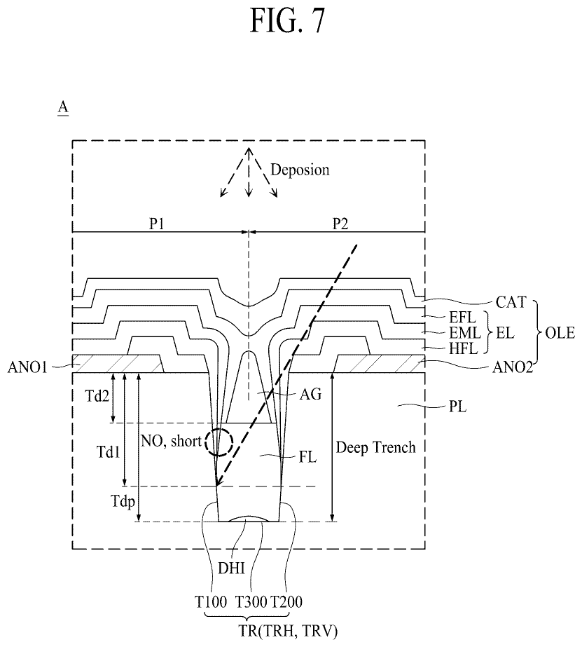

Hereinafter, referring to FIG. 7, another example of the deep trench structure according to the present disclosure will be explained. FIG. 7 is a cross-sectional view, as for explanation of deep-trench structure having an insulating structure between the hole functional layer and the electron functional layer according to another aspect, illustrating a structure of part ‘A’ indicated by a dotted rectangle in FIG. 4.

The structure of the trench shown in FIG. 7 may be very similar to the structure of the trench shown in FIG. 6. In FIG. 7, after the hole functional layer HFL and the light emitting layer EML are sequentially stacked, the filler FL may be filled in the trench TR. The same explanation mentioned in FIG. 6 will not be duplicated, and the main features of FIG. 7 will be explained.

After forming a trench TR as having the trench depth Tdp, a hole functional layer HFL and a light emitting layer EML may be sequentially deposited. The hole functional layer HFL and the light emitting layer EML may be deposited on the first sidewall T100 and the second sidewall T200 of the trench TR with a gradually decreasing thickness down to the deposition depth Td1. In some cases, residues of the hole functional layer HFL and the light emitting layer EML may remain on the bottom side T300 of the trench TR. However, from the deposition depth Td1 to the trench depth Tdp on the first sidewall T100 and the second sidewall T200, the hole functional layer HFL and the light emitting layer EML may be not deposited. Therefore, the hole functional layer HFL and the light emitting layer EML may have not a connected shape from the first sidewall T100 to the second sidewall T200 along the bottom side T300 by residues. Accordingly, at least, the hole functional layer HFL may be disconnected between the first pixel P1 and the second pixel P2. As a result, no lateral leakage current occurs due to holes moving along the hole functional layer HFL.

After that, the space inside the trench TR may be filled with a filler FL made of non-conductive material. The filler FL may fill the space from the bottom side T300 of the trench TR to a position of a certain depth Td2 from the top surface of the planarization layer PL corresponding to the top side of the trench TR. the filler depth Td2 may be smaller than the deposition depth Td1. The filler depth Td2 may be set so that the non-conductive filler FL may cover end portions of the hole function layer HFL and the light emitting layer EML deposited at lower portion of the trench TR including the portion where the light emitting layer EML is deposited too thin. For example, the filler depth Td2 may be less than 75% of the deposition depth Td1.

When the filler depth Td2 is larger than 75% of the deposition depth Td1, the filler FL may not cover the portion where the light emitting layer EML is deposited too thin. Accordingly, the electron functional layer EFL deposited on the light emitting layer EML may be directly and electrically connected to the hole functional layer HFL. In other case that the filler depth Td2 may be equal to the deposition depth Td1, the filler FL may completely fill the inner space of the trench TR. When the filler FL completely fills the trench TR, the electron functional layer EFL deposited thereafter may have a structure that is spaced apart from the hole functional layer HFL by at least the thickness of the light emitting layer EML.

After filling the filler FL is filled to about 50% to 75% of the deposition depth Td1, the electron functional layer EFL may be deposited. As the result, as shown in FIG. 7, the electron functional layer EFL may have a structure that is sufficiently spaced apart from the hole functional layer HFL such that it is not directly and electrically connected, at the sidewalls T100 and T200 of the trench TR.

The electron functional layer EFL may be deposited on the top side of the narrowed trench TR by sequentially stacking of the hole functional layer HFL and light emitting layer EML, so the electron functional layer EFL may be connected overall pixels. In addition, an air gap AG may be formed below the portion where the electron functional layer EFL is connecting between neighboring two pixels P. The air gap AG may refer to an empty space formed between the electron functional layer EFL and the filler FL. Even though it is not shown in FIG. 7, as the electron functional layer EFL may be deposited on the upper surface of the filler FL, the electron functional layer EFL may be connected from the first sidewall T100 to the second sidewall T200.

Until now, it has been outlined the reasons for forming a trench with a deep-trench structure, the problems that may occur in the deep-trench structure, and the structural features to solve the problems of the deep-trench. Hereinafter, the structure of the light emitting display device having deep-trench structure according to the present disclosure will be explained in detail using various aspects.

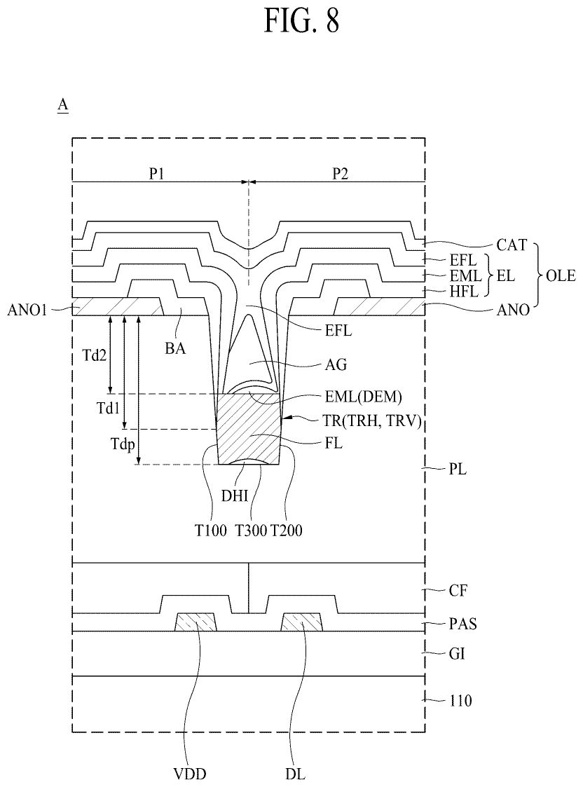

Hereinafter, referring to FIG. 8, a light emitting display device having a deep-trench structure according to a first aspect of the present disclosure will be explained. FIG. 8 is an enlarged cross-sectional view, as for explanation of a light emitting display device having a deep-trench structure according a first aspect of the present disclosure, illustrating a structure of part ‘A’ indicated by a dotted rectangle in FIG. 4.

Referring to FIG. 8, a light emitting display device according to the first aspect may comprise a substrate 110, a gate insulating layer GI, a data line DL, a driving current line VDD, a passivation layer PAS, a color filter CF and a planarization layer PL. The description of these elements is the same as that described in FIG. 4, so duplicate description is omitted.

On the planarization layer PL, a first pixel electrode ANO1 may be formed in the first pixel P1 and a second pixel electrode ANO2 may be formed in the second pixel P2. A trench TR may be formed between the first pixel electrode ANO1 and the second pixel electrode ANO2. The trench TR may be formed by etching the planarization layer PL with a trench depth Tdp.

The trench TR may include a first sidewall T100, a second sidewall T200 and a bottom side T300. The first sidewall T100 may be disposed on one side toward the first pixel P1, and the second sidewall T200 may be disposed on opposing side toward the second pixel P2. The bottom side T300 may be a surface connecting the bottom end of the first sidewall T100 and the bottom end of the second sidewall T200.

On the substrate 110 having the trench TR, a hole functional layer HFL may be deposited on the pixel electrodes ANO1 and ANO2 and the bank BA. The hole functional layer HFL may be deposited with a gradually decreasing thickness down to the deposition depth Td1. Here, the trench depth Tdp may be 120% to 150% of the deposition depth Td1. Since the hole functional layer HFL may not be deposited at the bottom of the trench TR, especially at the portions deeper than the deposition depth Td1, so the connectivity of the hole functional layer HFL may be disconnected between the first pixel P1 and the second pixel P2. In some cases, a dummy layer (or a first dummy layer) DHI formed by partially deposited the hole functional layer HFL may remain at the center of the bottom side T300 of the trench TR.

A filler FL made of non-conductive material may be filled inside of the trench TR on which the hole functional layer HFL is deposited. When the thickness of the light emitting layer EML deposited on the hole functional layer HFL is too thin, the electron functional layer EFL deposited on the light emitting layer EML may be directly connected to the hole functional layer HFL. The filler FL should have a filler depth Td2 to prevent this connectivity between the hole functional layer HFL and the electron functional layer EFL. For example, the filler depth Td2 may be 50% to 55% of the trench depth Tdp. At the same time, the filler depth Td2 may be smaller than the deposition depth Td1. Therefore, the filler depth Td2 may be 60% to 75% of the deposition depth Td1.

The cross-sectional shape after the filler FL is formed is explained by dividing it into the left region and the right region in FIG. 8. In FIG. 8, the left region and the right region are shown as having different profiles. However, the left region and the right region may have the same profile. For example, both the left region and the right region may have the same profile as the left region, or both the left region and the right region may have the same profile as the right region.

With the filler FL filling a portion of the trench TR, the light emitting layer EML may be deposited. For the left region, the light emitting layer EML may be extended form the edge of the top side met with the first side wall T100 to the upper surface of the filler FL. On the upper surface of the filler FL, the light emitting layer EML spaced apart from the light emitting layer EML deposited on the first sidewall T100 may be deposited. In this case, the light emitting layer EML deposited on the upper surface of the filler FL may be referred to a dummy light emitting layer DEM or a second dummy layer, as it is separated from the light emitting layer EML deposited on the first pixel electrode ANO1.

For the right region, the light emitting layer EML may be extended from the top side adjacent to the second sidewall T200 to the upper surface of the filler FL, and may be connected to the light emitting layer EML deposited on the upper surface of the filler FL. In this case, the light emitting layer EML deposited on the upper surface of the filler FL may not be dummy light emitting layer DEM, but a portion of the light emitting layer EML.

In other words, the light emitting layer EML may be disconnected between the first pixel P1 and the second pixel P2, as shown in the left region, or may be connected between the first pixel P1 and the second pixel P2, as shown in the right region. The light emitting layer EML is not the material in which hole or electron may be flow freely. Even though the light emitting layer EML is connected from the first pixel P1 to the second pixel P2, the lateral leakage current is not occurred through the light emitting layer EML.

After that, an electron functional layer EFL may be deposited on the light emitting layer EML. In the left region, the electron functional layer EFL may be extended down to a certain depth on the first sidewall T100. That is, the electron functional layer EFL may not reached on the upper surface of the filler FL. In the right region, the electron functional layer EFL may be deposited on the second sidewall T200, and on the upper surface of the filler FL.

Meanwhile, at the upper portion of the trench TR, the electron functional layer EFL may have a connected profile from the first pixel P1 to the second pixel P2. An air gap AG (or void) may be formed between the electron functional layer EFL and the filler FL. With a profile as the left region, the air gap AG may be a space surrounded by the electron functional layer EFL, the light emitting layer EML and the filler FL.

In the light emitting display device having a deep trench according to the first aspect, the hole functional layer HFL is not connected from the first pixel P1 to the second pixel P2 due to the deep trench structure, so that there is no lateral leakage current. In addition, as the filler FL covers the extended end portions of the hole functional layer HFL into the trench TR, the light emitting layer EML may not have any severely thinned portion where the hole functional layer HFL and the electron functional layer EFL may be directly and electrically connected. Therefore, the light emitting diode OLE may not be damaged or may not be malfunction.

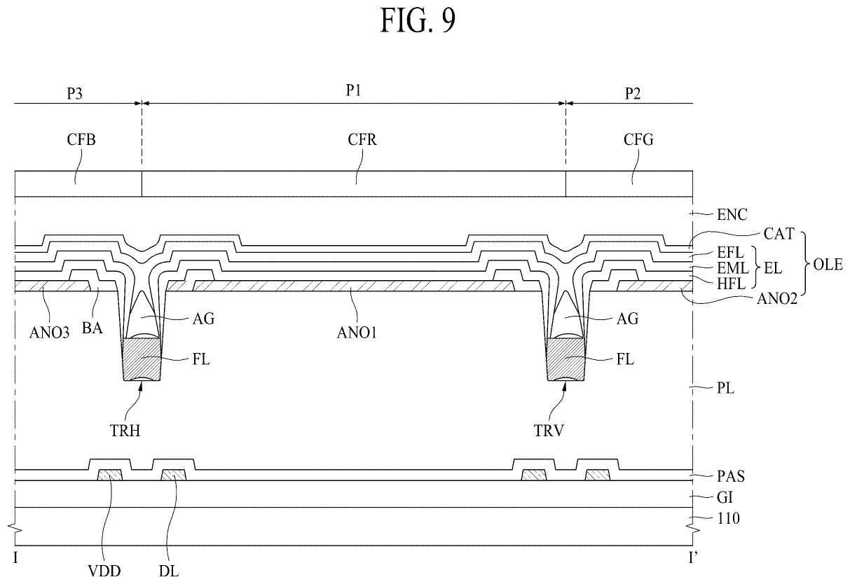

Hereinafter, referring to FIG. 9, a light emitting display device according to a second aspect of the present disclosure will be described. FIG. 9 is a cross-sectional view along cutting line II-II′ in FIG. 3, for illustrating a structure of a top emission type light emitting display device according to a second aspect of the present disclosure. FIG. 9 is a cross-sectional view illustrating a case where the deep trench and filler according to the present disclosure may be applied to a top emission type light emitting display device. The deep-trench structure of the second aspect may be very similar with the first aspect. Therefore, the description of the deep-trench structure and structural features by the filler FL may be omitted or briefly explained.

A light emitting display device according to a second aspect may include a plurality of pixels P disposed on a substrate 110. For example, a first pixel P1, a second pixel P2 and a third pixel P3 may be arrayed in succession. For a top emission type light emitting display device, since the light provided from the emission layer EL may be emitted toward the top side, the substrate 110 may include not only transparent materials but also opaque materials. On the substrate 110, a circuit element layer may be formed. The circuit element layer may include the switching thin film transistor ST and the driving thin film transistor DT explained in FIG. 4. Same description for the same elements explained in FIG. 4 may not be duplicated.

For the surrounding elements where the trench TR is formed, a gate insulating layer GI is deposited on the substrate 110. A data line DL and a driving current line VDD are disposed on the gate insulating layer GI. A passivation layer PAS may be deposited on the data line DL and the driving current line VDD. A planarization layer PL may be deposited on the passivation layer PAS.

The planarization layer PL may be deposited on the circuit element layer. The planarization layer PL may be formed of an organic material such as acryl resin, epoxy resin, phenolic resin, polyamide resin and polyimide resin. Otherwise, the planarization layer PL may be made of an inorganic material such as silicon nitride, aluminum nitride, zirconium nitride, titanium nitride, hafnium nitride, tantalum nitride, silicon oxide, aluminum oxide or titanium oxide.

On the planarization layer PL, a first pixel electrode ANO1 may be formed in the first pixel P1, a second pixel electrode ANO2 may be formed in the second pixel P2, and a third pixel electrode ANO3 may be formed in the third pixel P3. A bank BA may cover the circumferential areas of the pixel electrodes ANO1, ANO2 and ANO3. The central area of each pixel electrodes ANO1, ANO2 and ANO3 not covered by the bank BA may be defined as a light emission area.

A trench TR may be formed at the planarization layer PL between each pixel electrode ANO1, ANO2 and ANO3. Since the structure of the trench TR is the same as that described in the first aspect, detailed description may not be duplicated, or simply explained.

An organic emission layer EL and a common electrode CAT may be sequentially deposited on the pixel electrodes ANO1, ANO2 and ANO2 and the bank BA on the substrate 110 having the trench TR. The organic emission layer EL may include a hole functional layer HFL, a light emitting layer EML and an electron functional layer EFL sequentially stacked.

For the top emission type, the common electrode CAT may be made of a transparent conductive material including indium-tin-oxide (ITO) or indium-zinc-oxide (IZO) to transmit the light provided by the organic emission layer EL toward the top direction. Otherwise, the common electrode CAT may be made of a semi-transmissive metallic material including magnesium (Mg), silver (Ag) and magnesium-silver alloy (MgAg). The common electrode CAT may have a single layer structure or a multiple layer structure.

An encapsulation layer ENC may be deposited on the common electrode CAT. The encapsulation layer ENC may be made of an inorganic single layer including an inorganic material. Otherwise, the encapsulation layer ENC may have a multiple layer structure in which an inorganic layer including inorganic material and an organic layer including organic material may be alternately stacked.

A color filter CF may be deposited on the encapsulation layer ENC. For example, a red color filter CFR may be disposed in the first pixel P1, a green color filter CFG may be disposed in the second pixel P2 and a blue color filter CFB may be disposed in the third pixel P3.

In order that the light provided from the organic emission layer EL should be emitted in the direction in which the color filter CF is disposed, the pixel electrodes ANO1, ANO2 and ANO3 may be made of a metal material with excellent light reflectance. In addition, the common electrode CAT may be made of a transparent conductive material having an excellent light transparency.

In the light emitting display device having deep-trench structure according to the second aspect, due to the deep-trench structure same as the first aspect, the hole functional layer HFL may be not connected from the first pixel P1 to the second pixel P2, from the second pixel P2 to the third pixel P3, and from the third pixel P3 to the first pixel P1, so no lateral leakage current occurs.

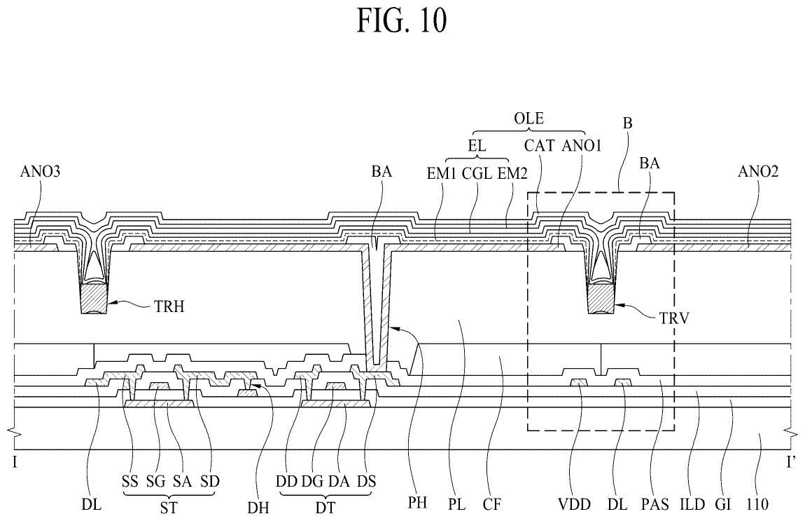

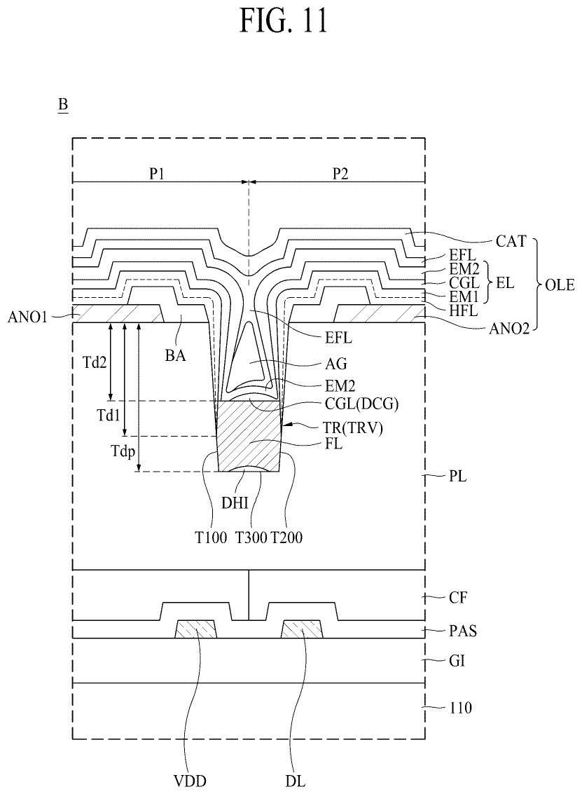

Hereinafter, referring to FIG. 10 and FIG. 11, a third aspect of the present disclosure will be explained. FIG. 10 is a cross-sectional view along cutting line I-I′ in FIG. 3, for illustrating a structure of a bottom emission type light emitting display device according to a third aspect of the present disclosure. FIG. 11 is an enlarged cross-sectional view, as for explanation of a light emitting display device having a deep-trench according a third aspect of the present disclosure, illustrating a structure of part ‘B’ indicated by a dotted rectangle in FIG. 10.

A light emitting display device according to third aspect may have very similar structure with the light emitting display device according to the first aspect. The different feature is that, in the third aspect, the organic emission layer may include two or more light emitting layers vertically stacked to generate white light. Other elements disposed between the substrate 110 and the planarization layer PL may be same with the light emitting display shown in FIG. 4, so same description may not be duplicated or may be explained briefly.

For example, the organic emission layer EL may include a first light emitting layer EM1 and a second light emitting layer EM2 for generating white light by mixing of a first light and a second light. In this case, a charge generation layer CGL may be disposed between the first light emitting layer EM1 and the second light emitting layer EM2. The first light emitting layer EM1 disposed between the pixel electrode ANO and the charge generation layer CGL may provide the first light, and the second light emitting layer EM2 disposed between the charge generation layer CGL and the common electrode CAT may provide the second light.

For the bottom emission type, the common electrode CAT may be made of a metal material having an excellent light reflectance. For example, the common electrode CAT may include one or more materials selected from silver (Ag), aluminum (Al), molybdenum (Mo), gold (Au), magnesium (Mg), calcium (Ca), and barium (Ba), or alloy of them.

Hereinafter, referring to FIG. 11, a deep-trench structure that disconnects electrical connectivity between pixels by the trench and a structure provided with a filler are explained. In addition, it will be described a structure for preventing the problem of the first light emitting layer EM1 failing to emit light which may be caused by the electrical conduction between the hole function layer HFL and the charge generation layer CGL in the deep-trench structure. When the hole functional layer HFL and the charge generation layer CGL is electrically connected or conducted, the first light emitting layer EM1 may not generate the light, resulting in device defects.

A gate insulating layer GI is deposited on the substrate 110. A driving current line VDD and a data line DL may be formed on the gate insulating layer GI. A passivation layer PAS may be deposited on the driving current line VDD and the data line DL. A color filter CF may be formed on the passivation layer PAS. For example, a red color filter may be disposed at the left region, and a green color filter may be disposed at the right region, as shown in FIG. 11.

A planarization layer PL may be deposited on the color filter CF. A pixel electrode ANO may be formed on the planarization layer PL. A bank BA is formed on the circumferential areas of the pixel electrode ANO. A trench TR may be disposed between two neighboring pixel electrodes ANO by etching the bank BA and the planarization layer PL disposed with certain depth. FIG. 11 shows only the structure of the vertical trench TRV disposed between the driving current line VDD and the data line DL, for convenience, but the horizontal trench TRH also has the same structure.

The trench TR may have a well shape including a first sidewall T100, a second sidewall T200 and a bottom side T300. The trench TR may have a trench depth Tdp. After forming the trench TR, a hole function layer HFL and a first light emitting layer EM1 are sequentially deposited on the pixel electrode ANO and the bank BA. On the first sidewall T100 and the second sidewall T200, the hole function layer HFL and the first light emitting layer EM1 may have a profile in which they may be deposited upper portions of the trench TR not perfectly deposited inside the trench TR. For example, the hole functional layer HFL and the first light emitting layer EM1 may have a thickness that gradually decreases until the deposition depth Td1, which is smaller than the trench depth Tdp, on the first sidewall T100 and the second sidewall T200. A dummy layer (or first dummy layer) DHI including the residues of the hole functional layer HFL and the first emitting layer EM1 may be deposited on the central portion of the bottom side T300, but may be not connected to the hole functional layer HFL and the first light emitting layer EM1 disposed on the first sidewall T100 and the second sidewall T200. As the result, the hole functional layer HFL and the first light emitting layer EM1 may be deposited on the entire surface of the substrate 110, but their connectivity may be disconnected or interrupted by the trench TR, so they may be separated per pixel P.

A filler FL made of a non-conductive material may be filled into the trench TR having the hole functional layer and the first light emitting layer EM1, up to the filler depth Td2. When the thickness of the first light emitting layer EM1 deposited on the hole functional layer HFL is too thin, the charge generation layer CGL deposited on the first light emitting layer EM1 may be directly connected to the hole functional layer HFL. The filler FL should have a filler depth Td2 to prevent this connectivity between the hole functional layer HFL and the charge generation layer CGL. For example, the filler depth Td2 may be 50% to 55% of the trench depth Tdp. At the same time, the filler depth Td2 may be smaller than the deposition depth Td1. Therefore, the filler depth Td2 may be 60% to 75% of the deposition depth Td1.

The cross-sectional shape after the filler FL is formed is explained by dividing it into the left region and the right region in FIG. 11. In FIG. 11, the left region and the right region are shown as having different profiles. However, the left region and the right region may have the same profile. For example, both the left region and the right region may have the same profile as the left region, or both the left region and the right region may have the same profile as the right region.

With the filler FL filling a portion of the trench TR, the charge generation layer CGL may be deposited. For the left region, the charge generation layer CGL may be extended form the edge of the top side met with the first side wall T100 to the upper surface of the filler FL. On the upper surface of the filler FL, the charge generation layer CGL spaced apart from the charge generation layer CGL deposited on the first sidewall T100 may be deposited. In this case, the charge generation layer CGL deposited on the upper surface of the filler FL may be referred to a dummy charge generation layer DCG or a second dummy layer, as it is separated from the charge generation layer CGL deposited on the first pixel electrode ANO1.

For the right region, the charge generation layer CGL may be extended from the top side adjacent to the second sidewall T200 to the upper surface of the filler FL, and may be connected to the charge generation layer CGL deposited on the upper surface of the filler FL. In this case, the charge generation layer CGL deposited on the upper surface of the filler FL may not be dummy charge generation layer DCG, but a portion of the charge generation layer CGL.

In other words, the charge generation layer CGL may be disconnected between the first pixel P1 and the second pixel P2, as shown in the left region, or may be connected between the first pixel P1 and the second pixel P2, as shown in the right region. Even though the charge generation layer CGL is continuously deposited from the first pixel P1 to the second pixel P2, the charge generation layer CGL may be very thinly deposited at the end corner of the upper surface of the filler FL. At this thinly deposited portion, the resistance of the charge generation layer CGL may be increased, so the charge may not be freely flow. That is, even though the charge generation layer CGL may be connected physically, but it may have the disconnected state electrically between the first pixel P1 and the second pixel P2. Accordingly, lateral leakage current between neighboring pixels along the charge generation layer CGL may be prevented or blocked.

A second light emitting layer EM2 may be deposited on the charge generation layer CGL. The second light emitting layer EM2 may have a profile in which it is connected along the first sidewall T100 of the trench TR, the upper surface of the filler FL, and the second sidewall T200 of the trench TR, so it deposited inside surface of the trench TR. Even though the second light emitting layer EM2 has a connectivity from the first pixel P1 to the second pixel P2, the charge may not be freely flow along the second light emitting layer EM2. Accordingly, the lateral leakage current does not occur.

An electron functional layer EFL may be deposited on the second light emitting layer EM2. As the deposition process of the electron functional layer EFL proceeds, the electron functional layer EFL becomes thicker at the first pixel P1 and the functional layer EFL becomes thicker at the second pixel P2 may be connected each other at the top area of the trench TR, so the electron functional layer EFL may close the upper space of the trench TR. As the result, the electron functional layer EFL may have a structure connected between all pixels on the entire surface of the substrate 110.

Over the trench TR, the electron functional layer EFL may be deposited as being connected from the first pixel P1 to the second pixel P2. An air gap AG (or void) may be formed between the electron functional layer EFL and the second light emitting layer EM2. For the case of the profile shown in the left region, the air gap AG may be a space surrounded by the electron functional layer EFL and the second light emitting layer EM2. For the case of the profile shown in the right region, the air gap AG may be a space surrounded by the electron functional layer EFL. That is, according to the third aspect, the air gap AG may have a structure in which it is surrounded by the electron functional layer EFL within the trench TR. Otherwise, the air gap AG may have a structure in which it is surrounded by the electron function layer EFL and the second light emitting layer EM2 within the trench TR.

A common electrode CAT is deposited on the electron functional layer EFL. As the electron functional layer EFL has a structure connected between all pixels on the entire surface of the substrate 110, the common electrode CAT may have a structure connected between all pixels. Even though it is not shown in figure, an encapsulation layer may be deposited on the common electrode CAT.

In the third aspect, the filler FL may fill some portions of the lower space of the trench TR, and the air gap AG is formed at the upper space of the trench TR. On the air gap AG, the electron functional layer EFL and the common electrode CAT may be sequentially stacked. With this structure, when the air gap AG is collapsed, the common electrode CAT may be cracked. Due to the cracked common electrode CAT, the sheet resistance of the common electrode CAT may not be maintained with a uniformed value. When the sheet resistance of the common electrode CAT is not uniform, the value of the common voltage applied to the common electrode CAT may have different values depending on the surface location of the common electrode CAT. This may cause defects in which luminance and image quality may not be uniform across the entire area of the display device. To prevent this problem, the air gap AG may be further filled with auxiliary filler made of non-conductive material.

In this case, the auxiliary filler may be filled up to the upper surface of the planarization layer PL corresponding to the top side of the trench TR. For another example, the auxiliary filler may be further filled up to upper surface of the bank BA. In this case, the electron functional layer EFL and the common electrode CAT may be sequentially stacked on the second light emitting layer EM2 and the auxiliary filler.

In the third aspect, for convenience of explanation, it is referred that the organic emission layer EL includes a hole functional layer HFL, a first light emitting layer EM1, a charge generation layer CGL, a second light emitting layer EM2 and an electron functional layer EFL. In detail, the organic emission layer may include a hole injection layer, a first hole transport layer, a first light emitting layer, a first electron transport layer, n-type charge generation layer, p-type charge generation layer, a second hole transport layer, a second light emitting layer, a second electron transport layer and an electron injection layer sequentially stacked. Here, the hole injection layer, the first hole transport layer, the first light emitting layer and the first electron transport layer may be referred to a first stack. The n-type charge generation layer and p-type charge generation layer may be referred to a charge generation layer CGL. The second hole transport layer, the second light emitting layer, the second electron transport layer and the electron injection layer may be referred to a second stack.

The light emitting display device according to the third aspect of the present disclosure has a structure in which the hole functional layer HFL is physically and electrically disconnected between the first pixel P1 and the second pixel P2 due to the deep-trench structure, so no lateral leakage current occurs. In addition, the hole functional layer HFL may be not directly and electrically connected to the charge generation layer CGL due to the filler FL, so the device may be prevented from being damaged or malfunction. Further, the length from the top side of the trench to the filler depth Td2 be formed to have a depth enough to physically and/or electrically disconnect the charge generation layer CGL between the first pixel P1 and the second pixel P2. Accordingly, the lateral leakage current via the charge generation layer CGL may be prevented. By preventing lateral leakage current, accurate color gamut may be implemented for each pixel. The security of the device may be ensured by preventing malfunction of the device that may occur due to the deep-trench structure. Therefore, the present disclosure may provide an excellent light emitting display device with clear and accurate color representation with low power consumption.

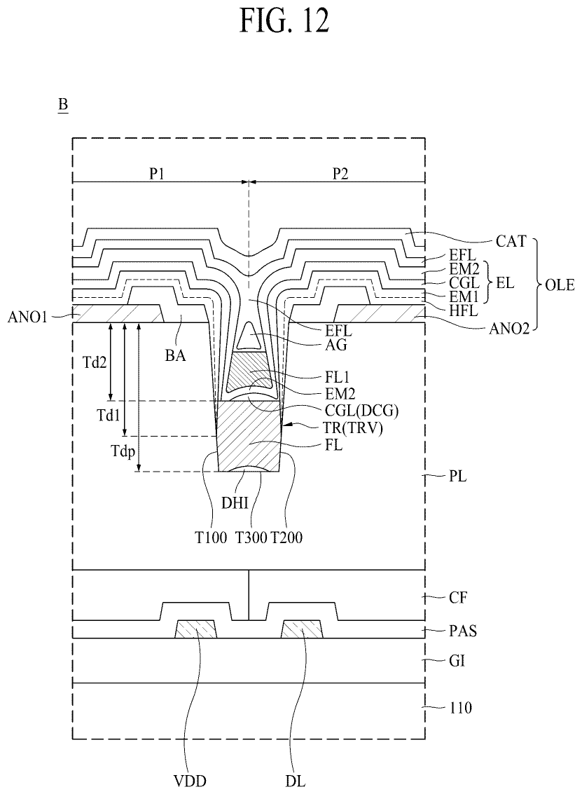

Hereinafter, referring to FIG. 12, a fourth aspect of the present disclosure will be explained. FIG. 12 is an enlarged cross-sectional view, as for explanation of a light emitting display device having a deep-trench according a fourth aspect of the present disclosure, illustrating a structure of part ‘B’ indicated by a dotted rectangle in FIG. 10.

The fourth aspect may have a structure for preventing a problem in which light may not be generated in the second light emitting layer EM2 because the electron function layer EFL is directly and electrically connected to the charge generation layer CGL in the third aspect shown in FIG. 11.

The light emitting display device according to the fourth aspect may have very similar structure with the light emitting display device according to the third aspect. The main features of the fourth aspect will be described in detail, and elements that overlap with the third aspect will be briefly explained or not mentioned.

The trench TR may have a well shape including a first sidewall T100, a second sidewall T200 and a bottom side T300. The trench TR may have a trench depth Tdp. After forming the trench TR, a hole functional layer HFL and a first light emitting layer EM1 are deposited on the pixel electrode ANO and the bank BA. Especially the hole functional layer HFL and the first light emitting layer EM1 are deposited on the first sidewall T100 and the second sidewall T200 with a thickness that gradually decreases until the deposition depth Td1 which is smaller than the trench depth Tdp. In the central portion of the bottom side T300, the hole functional layer HFL and the first light emitting layer EM1 may be partially deposited to form a dummy layer (or first dummy layer) DHI. The dummy layer DHI may not be connected to the hole functional layer HFL and the first light emitting layer EM1 deposited on the first sidewall T100 and the second sidewall T200. That is, the hole functional layer HFL and the first light emitting layer EM1 may be deposited on the entire surface of the substrate 110, but the connectivity may be interrupted by a trench TR, and separated on per pixel.

The inside of the trench TR where the hole functional layer HFL and the first light emitting layer EM1 are deposited may be filled with a filler FL made of a non-conductive material up to the filler depth Td2. The filler depth Td2 may be deep enough to prevent that the thickness of the first light emitting layer EM1 deposited on the hole functional layer HFL may be too thin, so the charge generation layer CGL later deposited on the first light emitting layer EM1 may be electrically connected to the hole functional layer HFL. The filler depth Td2 may be 50% to 55% of the trench depth Tdp, or 60% to 75% of the deposition depth Td1.

With the filler FL filling a portion of the trench TR, a charge generation layer CGL may be deposited thereon. For the left region, the charge generation layer CGL may be extended from the top of the first sidewall T100 to the upper surface of the filler FL. On the upper surface of the filler FL, the charge generation layer CGL may be deposited as being apart from the charge generation layer CGL deposited on the first sidewall T100. The charge generation layer deposited on the upper surface of the filler FL and separated from the charge generation layer CGL deposited on the first sidewall T100, as shown in left region, may be referred to as a dummy charge generation layer DCG or a second dummy layer. For the right region, the charge generation layer CGL may extended from the top of the second sidewall T200 to the upper surface of the filler FL, and be connected to the charge generation layer CGL deposited on the upper surface of the filler FL. That is, the charge generation layer CGL may be disconnected from the first pixel P1 to the second pixel P2, as shown in left region, but the charge generation layer CGL may be connected from the first pixel P1 to the second pixel P2, as shown in right region.

On the charge generation layer CGL, a second light emitting layer EM2 may be deposited. The second light emitting layer EM2 may have a profile that is deposited inside the trench TR while being connected along the first sidewall T100 of the trench TR, the upper surface of the filter FL and the second sidewall T200. Even though the second emitting layer EM2 has connectivity form the first pixel P1 to the second pixel P2, charges may not move freely along the second emitting layer EM2. That is, the lateral leakage current may be effectively prevented or be not occurred.

The structure of the fourth aspect explained now is the same as the third aspect. In the fourth aspect, an auxiliary filler FL1 may be filled inside of the trench TR where the second light emitting layer EM2 is deposited. Here, the auxiliary filler FL1 may be filled into the trench TR with a height smaller than the filler depth Td2, mentioned above aspects. For example, the auxiliary filler FL1 may be filled to 50% of the filler depth Td2 at least.

Referring to FIG. 11 again, the second light emitting layer EM2 may be thinly deposited on the charge generation layer CGL near the right corner of the upper surface of the filler FL. When the trench depth Tdp is very deep, the filler depth Td2 may also be deep. In this case, the second light emitting layer EM2 deposited on the first sidewall T100 and the second sidewall T200 near the end edge of the upper surface of the filler FL may have very thin thickness. After that, as depositing the electron functional layer EFL, due to the second light emitting layer EM2 having very thin thickness, the charge generation layer CGL may be electrically connected to the electron functional layer EFL. The auxiliary filler FL1 may be a non-conductive material for preventing the direct electrical conduction or connection between the charge generation layer CGL and the electron functional layer EFL.

As shown in FIG. 12, in the trench, the auxiliary filler FL1 may be filled from the upper surface of the filler FL to a certain height, so that the area having the thinned thickness of the second light emitting layer EM2 may be covered with the auxiliary filler FL1. After the auxiliary filler FL1 is deposited, the electron functional layer EFL may be deposited on the second light emitting layer EM2. As depositing process of the electron functional layer EFL proceeds, the electron functional layer EFL becomes thicker at the first pixel P1 and the electron function layer EFL becomes thicker at the second pixel P2, so the electron functional layer EFL of both sides may meet and be connected each other at the top of the trench TR and may made a shape that fills part of the upper space of the trench TR. As the result, the electron functional layer EFL may have a structure connected between all pixels P on the entire surface of the substrate 110.

In some cases, as shown in FIG. 12. The electron functional layer EFL may be deposited along the cross-sectional shape of the upper surface of the auxiliary filler FL1 and the second light emitting layer EM2. Accordingly, as the electron functional layer EFL is deposited, an air gap AG may be formed in the upper surface of the auxiliary filler FL1.

The light emitting display device according to the fourth aspect may have a structure in which the hole functional layer HFL is physically and electrically disconnected between the first pixel P1 and the second pixel P2, due to the deep-trench structure, so no lateral leakage current occurs. In addition, due to the deep-trench structure, the charge generation layer CGL may have a structure for physical and/or electrical disconnection between the first pixel P1 and the second pixel P2, between the second pixel P2 and the third pixel P3, and between the third pixel P3 and the first pixel P1. As the result, the lateral leakage current along the charge generation layer CGL may be prevented. By preventing the lateral leakage current, accurate color and color gamut may be realized for each pixel. In addition, by applying non-conductive filler and auxiliary filler, the malfunction of the device may be prevented by the deep-trench structure and the safety of the device may be ensured. Accordingly, the present disclosure may provide an excellent light emitting display device with clear and accurate color gamut representation with low power consumption.

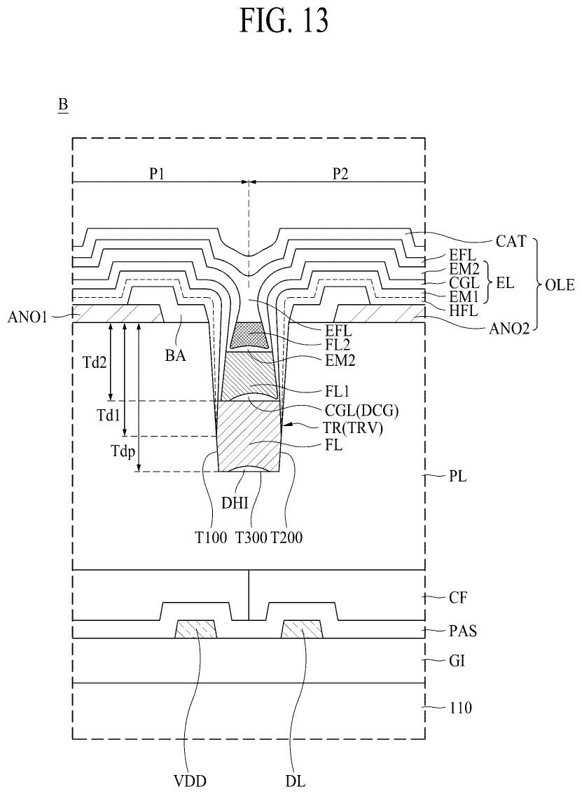

Hereinafter referring to FIG. 13, a fifth aspect of the present disclosure will be explained. FIG. 13 is an enlarged cross-sectional view, as for explanation of a light emitting display device having a deep-trench according a fifth aspect of the present disclosure, illustrating a structure of part ‘B’ indicated by a dotted rectangle in FIG. 10.

A light emitting display device according to a fifth aspect may have very similar structure with the light emitting display device according to the fourth aspect. In the fifth aspect, an auxiliary filler FL1 fills part of the space inside the trench TR after depositing the charge generation layer CGL.

The trench TR may have a well shape including a first sidewall T100, a second sidewall T200 and a bottom side T300. The trench TR may have a trench depth Tdp. After forming the trench TR, on the pixel electrode ANO and bank BA, a hole functional layer HFL and a first light emitting layer EM1 may be deposited as having a thickness that gradually decreases to the deposition depth Td1, which is smaller than the trench depth Tdp, on the first sidewall T100 and the second sidewall T200. The hole functional layer HFL and the first light emitting layer EM1 are deposited on the entire surface of the substrate 110, but their connectivity may be interrupted by the trench TR, so they may be separated per pixel P. In some cases, on the central portion of the bottom side T300, a dummy layer DHI (or a first dummy layer) including the same material with the hole functional layer HFL and the first light emitting layer EM1 may be deposited. However, the dummy layer DHI may be not connected to the hole functional layer HFL and the first light emitting layer EM1 deposited on the first sidewall T100 and the second sidewall T200.

The inside of the trench TR where the hole functional layer HFL and the first light emitting layer EM1 are deposited is filled with a filler FL made of a non-conductive material up to the filler depth TD2. When the thickness of the first light emitting layer EM1 deposited on the hole functional layer HFL is too thin, the charge generation layer CGL deposited on the first light emitting layer EM1 may be directly connected to the hole functional layer HFL. The filler FL should have a filler depth Td2 to prevent this connectivity between the hole functional layer HFL and the charge generation layer CGL.

With the filler FL filling a portion of the trench TR, the charge generation layer CGL may be deposited. For the left region, the charge generation layer CGL may be extended form the edge of the top side met with the first side wall T100 to the upper surface of the filler FL. On the upper surface of the filler FL, the charge generation layer CGL spaced apart from the charge generation layer CGL deposited on the first sidewall T100 may be deposited. As shown in left region, the charge generation layer CGL deposited on the upper surface of the filler FL may be referred to a dummy charge generation layer DCG or a second dummy layer, as it is separated from the charge generation layer CGL deposited on the first sidewall T100. For the right region, the charge generation layer CGL may be extended from the top side adjacent to the second sidewall T200 to the upper surface of the filler FL, and may be connected to the charge generation layer CGL deposited on the upper surface of the filler FL.

An auxiliary filler FL1 may be filled inside the trench TR where the charge generation layer CGL is deposited, with a certain depth. Here, the auxiliary filler FL1 may be filled up to 50% of the filler depth Td2 or a point higher than 50% point of the filler depth Td2. The auxiliary filler FL1 may be an element that priorly fills portions where the thickness of the second light emitting layer EM2 becomes too thin at the areas where the upper surface of the filler FL meets the first sidewall T100 and the second sidewall T200, in the remained space of trench TR after the filler FL is filled.

After forming the auxiliary filler FL1, a second light emitting layer EM2 may be deposited. The second light emitting layer EM2 may be deposited with the profile along the upper surface of the auxiliary filler FL1 and the charge generation layer CGL deposited on the first sidewall T100 and the second sidewall T200. That is, the second light emitting layer EM2 may have a structure that maintains connectivity while extending from the first pixel P1 to the second pixel P2.

As the result, the second light emitting layer EM2 may not have any portion which is too thinly deposited. After that, an electron functional layer EFL may be deposited. At this time, as the deposition process of the electron functional layer EFL, the electron functional layer EFL becomes thicker from the first pixel P1 and the second pixel P2, respectively, so the electron functional layers EFL from both sides may be in contact with each other to create a shape that fills an upper portion of the trench TR. That is, an air gap AG surrounded by the electron functional layer EFL may be formed as shown in FIG. 12. In some cases, the electron functional layer EFL may be filled the air gap AG formed on the upper space of the trench TR to be connected from the first pixel P1 to the second pixel P2.

When the air gap AG is formed as shown in FIG. 12, although there is no problem when the air gap AG is left as is, the common electrode CAT deposited thereon may be lost or damaged as the air gap AG collapses. In this case, the sheet resistance of the common electrode CAT may have deviations, which may cause problems with display performance.

To prevent these problems, an upper filler FL2 may be filled in the remaining space of the trench TR where the second light emitting layer EM2 is deposited. For an example, the upper filler FL2 may fill the remaining space of the trench TR up to the upper surface of the planarization layer PL corresponding to the top side of the trench TR. For another example, the upper filler FL2 may be filled to a position higher than the upper surface of the planarization layer PL. For instance, the upper filler FL2 may be filled up to the same level with the upper surface of the bank BA.

After forming the upper filler FL2, an electron functional layer EFL may be deposited. It has a structure in which an upper filler FL2 and a second light emitting layer EM2 may be interposed between the electron functional layer EFL and the charge generation layer CGL. Therefore, the electron functional layer EFL may not have a direct electrical connection to the charge generation layer CGL. In addition, by filling remaining spaces of the trench TR with the upper filler FL2, the common electrode CAT deposited on the electron functional layer EFL may not be sunk down, so uniform common voltage may be maintained overall of the common electrode CAT.

The light emitting display device according to fifth aspect of the present disclosure may have a structure in which the hole functional layer HFL may be physically and electrically disconnected between the first pixel P1 and the second pixel P2 due to the deep-trench structure. In addition, the charge generation layer CGL may have a structure in which there is a physical and/or electrical disconnection between the first pixel P1 and the second pixel P2. As the result, no lateral leakage current occurs through the hole functional layer HFL and/or the charge generation layer CGL. By preventing the lateral leakage current, accurate color may be realized for each pixel P. Further, by applying non-conductive fillers and auxiliary fillers, malfunction of the device due to the deep-trench structure may be prevented, and the safety of the device may be ensured. Moreover, by filling the remaining empty space of the trench TR with a non-conductive upper filler, the possibility of damage to the common electrode may be prevented in advance. Accordingly, an excellent light emitting display device may be provided with clear, vivid and accurate color gamut representation with low power consumption.

The features, structures, effects and so on described in the above examples of the present disclosure are included in at least one example of the present disclosure, and are not limited to only one example. Furthermore, the features, structures, effects and the likes explained in at least one example may be implemented in combination or modification with respect to other examples by those skilled in the art to which this disclosure belongs. Accordingly, contents related to such combinations and variations should be construed as being included in the scope of the present disclosure.

It will be apparent to those skilled in the art that various modifications and variations may be made in the present disclosure without departing from the spirit or scope of the disclosures. Thus, it is intended that the present disclosure covers the modifications and variations of this disclosure provided they come within the scope of the appended claims and their equivalents. These and other changes may be made to the aspects in light of the above-detailed description. In general, in the following claims, the terms used should not be construed to limit the claims to the specific aspects disclosed in the specification and the claims, but should be construed to include all possible aspects along with the full scope of equivalents to which such claims are entitled. Accordingly, the claims are not limited by the disclosure.

What is claimed is:

1. A light emitting display device comprising:
a substrate including a first pixel and a second pixel;
a planarization layer disposed on an entire surface of the substrate;
a trench depressed into the planarization layer with a first depth, the trench including a first sidewall near the first pixel, a second sidewall near the second pixel and a bottom side connecting bottom ends of the first sidewall and the second sidewall;
a first pixel electrode disposed at the first pixel on the planarization layer;
a second pixel electrode disposed at the second pixel on the planarization layer;
a hole functional layer disposed on the first pixel electrode and the second pixel electrode, and extended from a top side of the trench to a second depth smaller than the first depth on the first sidewall and the second sidewall of the trench;
a filler disposed from the bottom side to a third depth smaller than the second depth;
a light emitting layer disposed on the hole functional layer, and extended from the top side of the trench to an upper surface of the filler on the first sidewall and the second sidewall;
an electron functional layer disposed on the light emitting layer, and connected from the first pixel to the second pixel; and
a common electrode disposed on the electron functional layer, and connected from the first pixel to the second pixel.

2. The light emitting display device according to claim 1, further comprising a first dummy layer disposed between the bottom side of the trench and the filler, and including a same material with the hole functional layer,
wherein the hole functional layer is disconnected from the first dummy layer at a lower portion of the trench.

3. The light emitting display device according to claim 1, wherein the filler contacts some of the hole functional layer at the first sidewall and the second sidewall.

4. The light emitting display device according to claim 1, further comprising a second dummy layer disposed on a central portion of the upper surface of the filler, and including a same material with the light emitting layer,
wherein the light emitting layer is extended from the top of the trench to the upper surface of the filler at the first sidewall and the second sidewall, and is physically disconnected from the second dummy layer.

5. The light emitting display device according to claim 1, further comprising a second dummy layer disposed on a central upper surface of the filler, and including a same material with the light emitting layer,
wherein the light emitting layer is physically connected to the second dummy layer at edge corners of the upper surface of the filler, and is electrically disconnected from the second dummy layer.

6. The light emitting display device according to claim 1, wherein the hole functional layer is disconnected from the first pixel electrode to the second pixel electrode between the first sidewall and the second sidewall, and
wherein the hole functional layer is physically disconnected from the electron functional layer by the filler.

7. The light emitting display device according to claim 1, further comprising:
an air gap disposed between the electron functional layer disposed on the first sidewall and the second sidewall and the filler; and
an auxiliary filler filling the air gap.

8. A light emitting display device comprising:
a substrate including a first pixel and a second pixel;
a planarization layer disposed on an entire surface of the substrate;
a trench depressed into the planarization layer with a first depth, the trench including a first sidewall near the first pixel, a second sidewall near the second pixel and a bottom side connecting bottom ends of the first sidewall and the second sidewall;
a first pixel electrode disposed at the first pixel on the planarization layer;
a second pixel electrode disposed at the second pixel on the planarization layer;
a light emitting layer disposed on the first pixel electrode and the second pixel electrode, and extended from a top side of the trench to a second depth smaller than the first depth on the first sidewall and the second sidewall of the trench;
a filler disposed from the bottom side to a third depth smaller than the second depth;
an electron functional layer disposed on the light emitting layer, and connected from the first pixel to the second pixel; and
a common electrode disposed on the electron functional layer, and connected from the first pixel to the second pixel.

9. The light emitting display device according to claim 8, further comprising:
an air gap disposed between the electron functional layer disposed on the first sidewall and the second sidewall and the filler; and
a hole functional layer under the light emitting layer.

10. The light emitting display device according to claim 9, wherein the hole functional layer is disconnected from the first pixel electrode to the second pixel electrode between the first sidewall and the second sidewall, and
wherein the hole functional layer is physically disconnected from the electron functional layer by the filler.

11. A light emitting display device comprising:
a substrate including a first pixel and a second pixel;
a planarization layer disposed on an entire surface of the substrate;
a trench depressed into the planarization layer with a first depth, the trench including a first sidewall near the first pixel, a second sidewall near the second pixel and a bottom side connecting bottom ends of the first sidewall and the second sidewall;
a first pixel electrode disposed at the first pixel on the planarization layer;
a second pixel electrode disposed at the second pixel on the planarization layer;
a first light emitting layer disposed on the first pixel electrode and the second pixel electrode, and extended from a top side of the trench to a second depth smaller than the first depth on the first sidewall and the second sidewall of the trench;
a filler disposed from the bottom side to a third depth smaller than the second depth;
a charge generation layer disposed on the first light emitting layer, extending from the top side of the trench to an upper surface of the filler on the first sidewall and the second sidewall;
a second light emitting layer disposed on the charge generation layer, and connected from the first pixel to the second pixel;
an electron functional layer disposed on the second light emitting layer, and connected from the first pixel to the second pixel; and
a common electrode disposed on the electron functional layer, and connected from the first pixel to the second pixel.

12. The light emitting display device according to claim 11, further comprising a first dummy layer disposed between the bottom side and the filler, and including a same material with the first light emitting layer,
wherein the first light emitting layer is disconnected from the first dummy layer at a lower portion of the trench.

13. The light emitting display device according to claim 11, wherein the filler contacts some of the first light emitting layer at the first sidewall and the second sidewall.

14. The light emitting display device according to claim 11, further comprising a second dummy layer disposed on a central portion of the upper surface of the filler, and including a same material with the charge generation layer,
wherein the charge generation layer is extended from the top of the trench to the upper surface of the filler at the first sidewall and the second sidewall, and is physically disconnected from the second dummy layer.

15. The light emitting display device according to claim 11, further comprising a second dummy layer disposed on a central portion of the upper surface of the filler, and including a same material with the charge generation layer,
wherein the charge generation layer is physically connected to the second dummy layer at edge corners of the upper surface of the filler, and is electrically disconnected from the second dummy layer.

16. The light emitting display device according to claim 11, further comprising a hole functional layer disposed under the first light emitting layer.

17. The light emitting display device according to claim 16, wherein the first light emitting layer and the hole functional layer are disconnected from the first pixel electrode to the second pixel electrode between the first sidewall and the second sidewall, and
wherein the hole functional layer is physically disconnected from the electron functional layer by the filler.

18. The light emitting display device according to claim 11, further comprising:
an air gap surrounded by the second light emitting layer, the electron functional layer and the filler; and
an auxiliary filler filling the air gap.

19. The light emitting display device according to claim 11, further comprising:
an auxiliary filler filled up to a depth smaller than the third depth, and contacting the charge generation layer inside the trench; and
an air gap surrounded by the second light emitting layer, the electron functional layer and the filler.

20. The light emitting display device according to claim 11, further comprising:
an auxiliary filler filled up to a depth smaller than the third depth, and contacting the charge generation layer inside the trench; and
an upper filler filled an upper space of the trench, the upper space corresponding to a space from the second light emitting layer on the auxiliary filler to the top side of the trench,
wherein the electron functional layer is disposed on the second light emitting layer and the upper filler.
